(19) United States
(12) Patent Application Publication
(10) Pub. No.: US 2010/0037943 A1
(43) Pub. Date: Feb. 18, 2010

(54) VERTICAL MULTIJUNCTION CELL WITH TEXTURED SURFACE

(76) Inventor: Bernard L. Sater, Strongsville, OH (US)

Correspondence Address: TUROCY & WATSON, LLP, 127 Public Square, 57th Floor, Key Tower, CLEVELAND, OH, 44114, US

(21) Appl. No.: 12/536,982

(22) Filed: Aug. 6, 2009

Related U.S. Application Data
(60) Provisional application No. 61/088,921, filed on Aug. 14, 2008.

(51) Int. Cl. H01L 31/0236; H01L 31/18

(52) U.S. Cl. 136/255; 136/252; 438/71; 257/E31.13

(57) ABSTRACT

Systems and methods that mitigate bulk recombination losses in a vertical multi junction (VMJ) cell via a texturing on a light receiving surface. The textures can be in form of cavity shaped grooves, and a plane containing repetitive cross section configurations thereof is substantially perpendicular to the direction of stacking the unit cells that form the VMJ. Incident light can be refracted in the plane that includes the cross section configurations and away from the p+ and n+ diffused doped regions.

### CROSS REFERENCE TO RELATED APPLICATIONS

This application claims the benefit of U.S. Provisional Application No. 61/088,921 filed on 14 Aug. 2008 entitled “VERTICAL MULTIJUNCTION CELL WITH TEXTURED SURFACE” the entirety of this application is hereby incorporated by reference.

### BACKGROUND

Limited supply of fossil energy resources and their associated global environmental damage have compelled market forces to diversify energy resources and related technologies. One such resource that has received significant attention is solar energy, which employs photovoltaic systems to convert light into electricity. Typically, photovoltaic production has been doubling every two years, increasing by an average of 48 percent each year since year 2002, making it the world's fastest-growing energy technology. By midyear 2008, estimates for cumulative global solar energy production stands to at least 12,400 megawatts.

Accordingly, solar concentrators represent promising approaches for mitigating costs associated with photovoltaic (PV) cells. In general, PV concentrators employ low cost materials such as large area glass mirrors to intensify sunlight, and reduce amount of required semiconductor material deemed expensive. In effect, PV concentrators can reduce a dollar-to-watt cost barrier, which typically impedes conventional PV Industry. Moreover, PV concentrators can provide performance advantages, as high cell efficiencies and sun tracking become prevalent.

A significant challenge to achieve increased cost effectiveness is enabling silicon solar cells or photovoltaic cells to operate efficiently at high intensities, while at the same time maintaining relatively low manufacturing costs. To meet such challenge, high voltage silicon vertical multi-junction (VMJ) photovoltaic cells have been proposed as an attractive solution. As compared to silicon photovoltaic cells with a horizontal pn junction at the top surface (which are fabricated with substantially low resistivity silicon with low minority carrier lifetime)—the VMJ with vertical pn junctions are fabricated with high resistivity silicon with high minority carrier lifetime.

Nonetheless challenges remain as physics of electron-hole carrier pairs produced in photovoltaic cells at high intensities are rather complex. For example, multitude of physical parameters—often interrelated—are involved, such as: surface recombination velocities, carriers mobility and concentrations, emitters (diffusions) reverse saturation currents, minority carrier lifetimes, band gap narrowing, built-in electrostatic fields, various recombination mechanisms/associated rates, and the like.

Moreover, in such photovoltaic cells mobility decreases rapidly with increasing carrier density, and Auger recombination increases rapidly with intensity as the cube of the carrier density. For example, the Auger recombination rate in the bulk region increases with bulk volume and as the cube of carrier density. As such, if VMJ unit cell volume is doubled—the total bulk recombination can potentially increase sixteen-fold for the same intensity, as both volume and current doubles. Hence, at high intensities, Auger recombination in the bulk region volume degrades carrier collection efficiency and performance, which favors thinner starting wafers for unit cells and less cell thickness to decrease volume.

Nonetheless, employing thinner starting wafers can increase manufacturing costs—since more wafers are required in a given VMJ cell design. Furthermore, designing for less cell thickness can decrease carrier collection efficiency (e.g., for weakly absorbed longer wavelengths of the solar spectrum.) For example with a thickness of 100 microns, the maximum current is only 90% of the full short-circuit current that may ideally be generated in conventional planar silicon photovoltaic cells under normal incident sunlight.

### SUMMARY

The following presents a simplified summary in order to provide a basic understanding of some aspects of the claimed subject matter. This summary is not an extensive overview. It is not intended to identify key/critical elements or to delineate the scope of the claimed subject matter. Its sole purpose is to present some concepts in a simplified form as a prelude to the more detailed description that is presented later.

The subject innovation mitigates bulk recombination losses in a vertical multi junction (VMJ) cell via a texturing on its light receiving surface. The textures can be in form of cavity shaped grooves—as “V” shaped cross section configurations, “U” shaped cross configurations, and the like—wherein a plane that includes such cross section configuration is substantially perpendicular to the direction of stacking the unit cells that form the VMJ. In one aspect, a plane that includes substantially repetitive cross sections (e.g. cross-sectioning a direction that grooves are extended thereon) is substantially perpendicular to the direction of stacking the unit cells. Such an arrangement facilitates directing the refracted light away from the p+ and n+ diffused doped regions of the VMJ—while at the same time creating desired carriers in a decreasing volume. Accordingly, incident light can be refracted in the plane that includes the cross section configuration, and which is substantially perpendicular to the direction of stacking the unit cells.

It is to be appreciated that the texturing for the VMJ of the subject innovation is different from prior art for conventional silicon photovoltaic cell textures—both in terms of orientation of PN junctions; and/or interaction with incident light. For example, conventional silicon photovoltaic cells are typically textured to incline the penetration of the light, so that more of the longer wavelengths are absorbed closer to PN junctions (positioned horizontally) for better current collection of carriers—and hence mitigate poor spectral response to longer wavelengths in the solar spectrum. In contrast, such is not required in the VMJ of the subject innovation that includes vertical junctions, and hence already provides for an enhanced spectral response to the longer wavelengths in the solar spectrum.

In a particular aspect, an outcome for implementing grooves of the subject innovation (e.g., V grooves) is to mitigate bulk recombination losses by reducing the bulk volume—(as opposed to conventional solar surfaces with texturing, which reduce reflection, or cause reflected or refracted light to become closer to the junctions). In particular, the VMJ cell has demonstrated better carrier current collection for both the short wavelengths and the long wavelengths, wherein the short wavelength response is due to eliminating a highly doped horizontal junction at the top surface, and the long wavelength respond is due to the enhanced collection efficiency of vertical junctions.) As another example, if instead of the cavity shaped grooved texture of the subject innovation, other textures (e.g., random, pyramids, domes, and similar raised configurations) were implemented as part of the VMJ, incident light becomes refracted in all directions, resulting in light absorption in the p+ and n+ diffused regions and hence reduced efficiency.

According to a related methodology, initially a VMJ can be formed by stacking multiple cell units, wherein each cell itself can include a plurality of parallel semiconductor substrates or layers that are stacked together. Each layer can consist of impurity doped semiconductor material that form a PN junction, and further include a “built-in” electrostatic drift field that enhance minority carrier movement toward such PN junction. Subsequently a plurality of such cell units are integrated to shape a VMJ. Next, on a surface of the VMJ cell that receives light, cavity shaped grooves can be formed (e.g., via a dicing saw)—wherein the plane that includes the cross section configuration is substantially perpendicular to the direction of stacking the unit cells, which form the VMJ. Accordingly, incident light can be refracted in the plane that includes the repetitive cross section configurations, and which is substantially perpendicular to the direction of stacking the unit cells (e.g., hence supply a higher absorption for a given depth.) Moreover, various back surface(s) and side surface(s) with reflection coatings can be implemented in conjunction with various aspects of the subject innovation.

In a related aspect, a grooved surface of the subject innovation further improves carrier collection, while reducing bulk recombination losses. For example, the V-grooves can be positioned perpendicular to the p+nn+(or n+pp+) unit cells, to increase optical absorption paths of the longer wavelengths in the solar spectrum and enable light absorption being substantially confined within the n-type bulk region of p+nn+ unit cells. Moreover, such V-grooves can have an anti-reflection coating applied to improved incident light absorption in the cell.

To the accomplishment of the foregoing and related ends, certain illustrative aspects (not to scale) of the claimed subject matter are described herein in connection with the following description and the annexed drawings. These aspects are indicative of various ways in which the subject matter may be practiced, all of which are intended to be within the scope of the claimed subject matter. Other advantages and novel features may become apparent from the following detailed description when considered in conjunction with the drawings. The subject drawings are schematic in nature and not necessarily drawn to scale.

### BRIEF DESCRIPTION OF THE DRAWINGS

FIG. 1 illustrates a schematic perspective of a textured or grooved surface as part of vertical multi junction (VMJ) cell in accordance with an aspect of the subject innovation.

FIG. 2 illustrates exemplary cross sections for implementing grooves of the subject innovation.

FIG. 3 illustrates an exemplary stacking of cell units to form a VMJ with a grooved surface according to an aspect of the subject innovation.

FIG. 4 illustrates a particular unit cell that in part forms a VMJ according to an aspect of the subject innovation.

FIG. 5 illustrates a related methodology of creating a VMJ with grooved surfaces to mitigate bulk recombination losses according to an aspect of the subject innovation.

### DETAILED DESCRIPTION

The various aspects of the subject innovation are now described with reference to the annexed drawings, wherein like numerals refer to like or corresponding elements throughout. It should be understood, however, that the drawings and detailed description relating thereto are not intended to limit the claimed subject matter to the particular form disclosed. Rather, the intention is to cover all modifications, equivalents, and alternatives falling within the spirit and scope of the claimed subject matter.

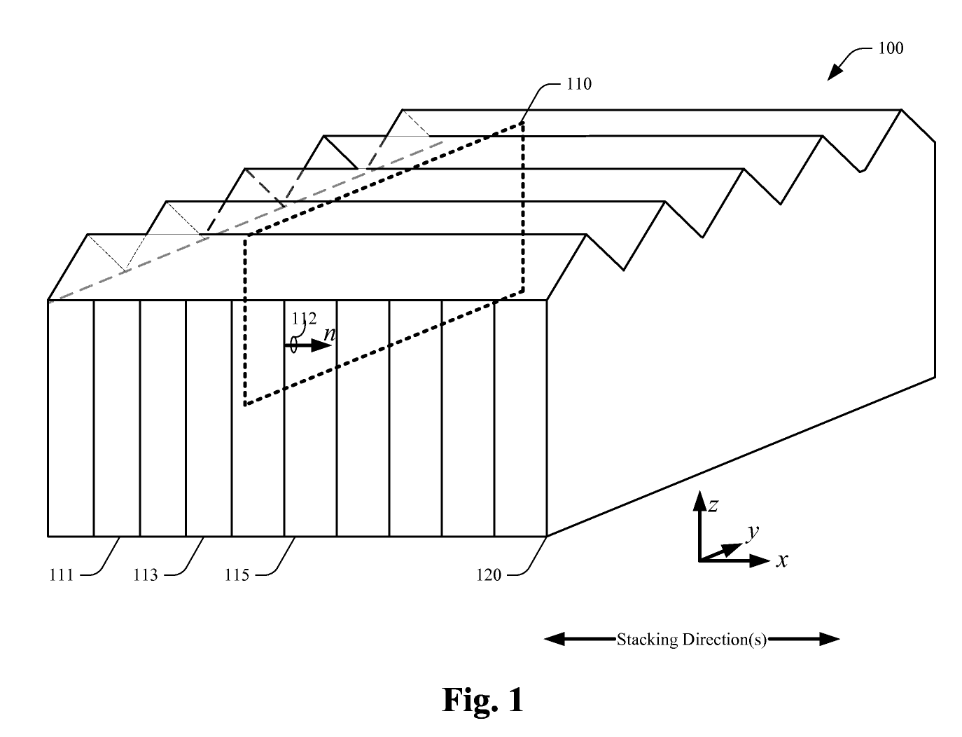

FIG. 1 illustrates a schematic perspective of a grooved surface 100 as part of a vertical multi junction (VMJ) cell 120 in accordance with an aspect of the subject innovation. Such an arrangement for texturing 100 enables the refracted light to be directed away from the p+ and n+ diffused doped regions—while at the same time creating desired carriers. Accordingly, incident light can be refracted in the plane 110 having a normal vector n. Such plane 110 is parallel to the PN junction planes of the VMJ 120, and can include the cross section configuration of the grooves 100. Moreover, an anti-reflection coating can be applied to the textured 100 surface to increase incident light absorption in the cell. Put differently, the orientation of the plane 110 is substantially perpendicular to the direction of stacking the unit cells 111, 113, 115. It is to be appreciated that other non-perpendicular orientations can also be contemplated (e.g., crystalline planes being exposed at various angles) and all such aspects are to be considered within the realm of the subject innovation.

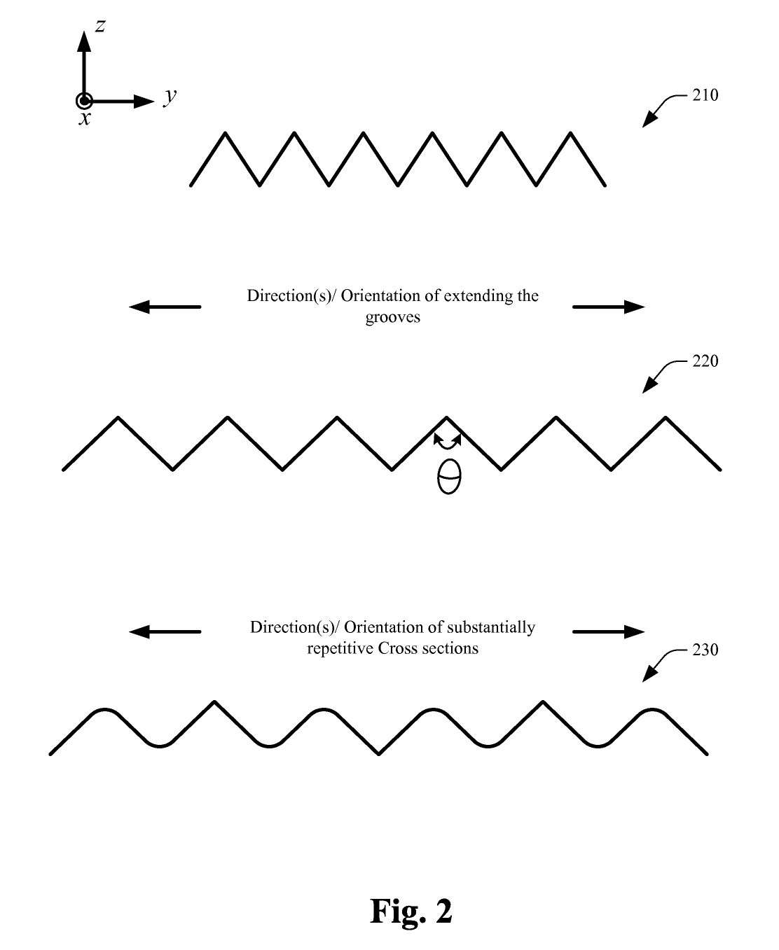

FIG. 2 illustrates exemplary textures for grooving a surface of the VMJ, which receives light thereon. Such grooving can be in form of cavity shaped grooves—for example, as “V” shaped cross section configurations having a variety of angles θ, (e.g., 0°<θ<180°)“U” shaped cross configurations, and the like—wherein the plane that includes the cross section configuration is substantially perpendicular to the direction of stacking the unit cells that form the VMJ, and/or substantially parallel to the PN junctions of the VMJ. It is to be appreciated that the texturing 210, 220, 230 for the VMJ of the subject innovation is different from prior art for conventional silicon photovoltaic cell textures, in orientation of PN junctions and/or interaction with incident light. For example, conventional silicon photovoltaic cells are typically textured to incline the penetration of the light, so that more of the longer wavelengths are absorbed closer to PN junctions (positioned horizontally) for better current collection of carriers—and hence mitigate poor spectral response to longer wavelengths in the solar spectrum. In contrast, such is not required in the VMJ of the subject innovation that includes vertical junctions, and which already provides an enhanced spectral response to the longer wavelengths in the solar spectrum.

Rather, one aspect for implementing grooves of the subject innovation (e.g., V grooves) is to mitigate bulk recombination losses by reducing the bulk volume—(as opposed to conventional solar surfaces with texturing, which reduce reflection, or cause reflected or refracted light to become closer to the junctions). In particular, VMJ cell has demonstrated better carrier current collection for both the short wavelengths and the long wavelengths, wherein the short wavelength response is due to eliminating a highly doped horizontal junction at the top surface and the long wavelength respond is due to the enhanced collection efficiency of vertical junctions.) As another example, if instead of the cavity shaped grooved texture of the subject innovation, other textures (e.g., random, pyramids, domes, and similar raised configurations) were implemented as part of the VMJ, incident light becomes refracted in all directions, resulting in light absorption in the p+ and n+ diffused regions and hence reduced efficiency. It is to be appreciated that such “U” and “V” shaped grooves are exemplary in nature and other configurations are well within the realm of the subject innovation.

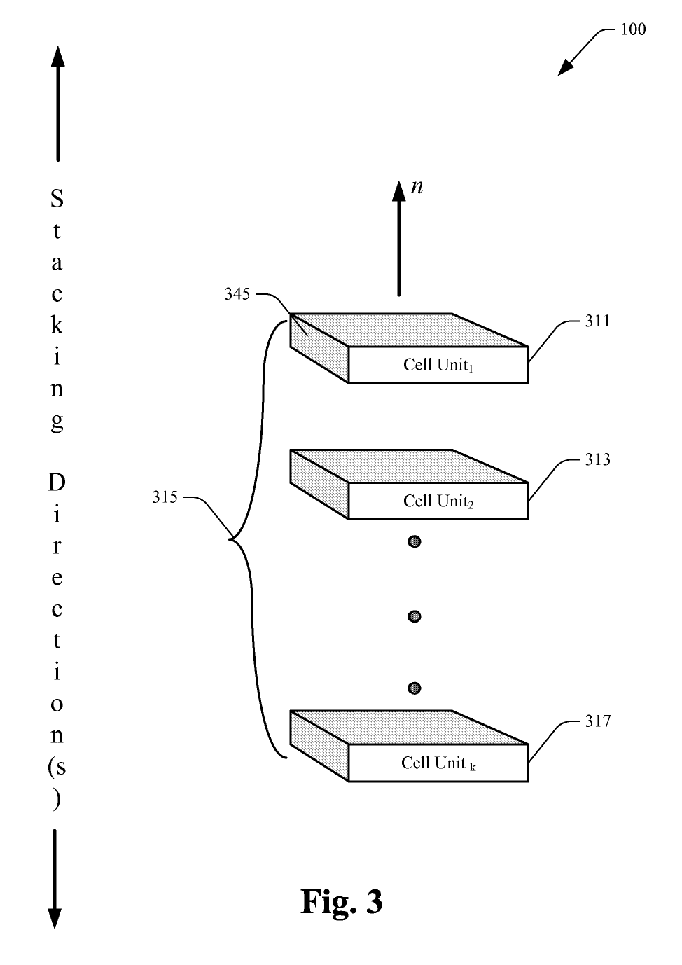

FIG. 3 illustrates an arrangement of unit cells 311, 313, 317 that can implement grooved texture on a side 345 in accordance with an aspect of the subject innovation. As explained earlier, The VMJ 315 itself is formed from a plurality integrally bonded cell units 311, 313, 317 (1 to k, k being an integer), wherein each cell unit itself is formed from stacked substrates or layers (not shown). For example, each cell unit 311 can include a plurality of parallel semiconductor substrates stacked together, and consisting of impurity doped semiconductor material, which form a PN junction and a “built-in” electrostatic drift field that enhance minority carrier movement toward such PN junction. It is to be appreciated that various N+-type and P-type doping layer formation can be implemented as part of the cell units and such arrangements are well within the realm of the subject innovation.

Accordingly, the textures on a light receiving surface 345 facilitate refracted light to be directed away from the p+and n+diffused doped regions—while at the same time creating desired carriers are created. Hence, incident light can be refracted in the plane that includes the cross section configuration, and which is substantially perpendicular to the direction of stacking the unit cells (e.g., perpendicular to vector n.)

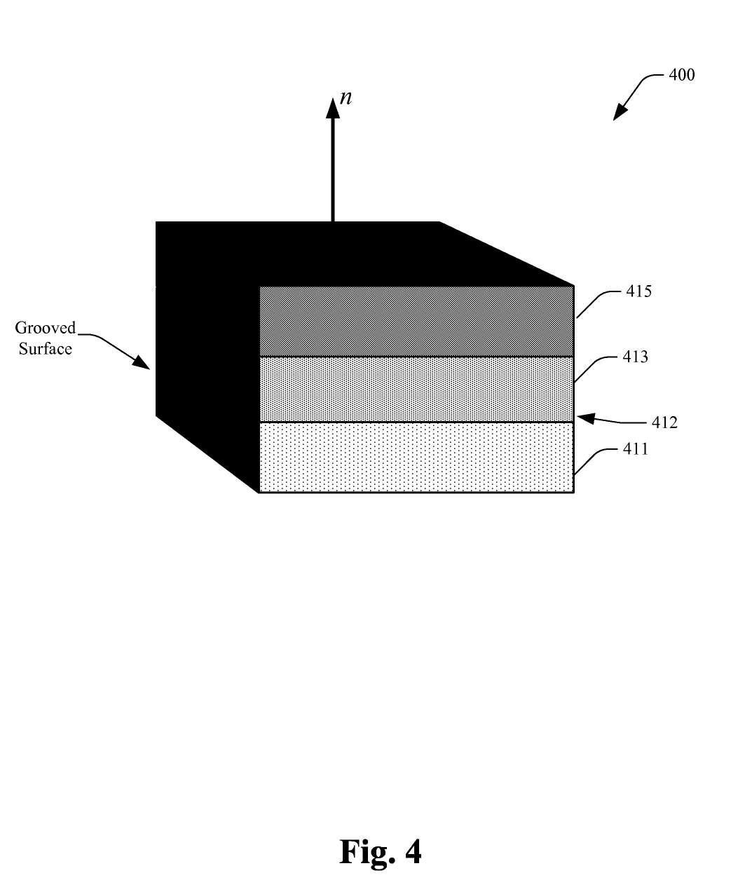

FIG. 4 illustrates a particular aspect of a unit cell, an array of which can form a VMJ cell having a textured grooving of the subject innovation. The unit cell 400 includes layers 411, 413, 415 stacked together in a substantially parallel arrangement. Such layers 411, 413, 415 can further include impurity doped semiconductor material, wherein layer 413 is of one conductivity type and layer 411 is of an opposing conductivity type—to define a PN junction at intersection 412. Likewise, layer 415 can be of the same conductivity type as layer 413—yet with substantially higher impurity concentration, hence generating a built-in electrostatic drift field that enhances minority carrier movements toward the PN junction 412. Such unit cells can be integrally bonded together to form a VMJ, and surface grooved according to various aspects of the subject innovation.

According to a further aspect, to fabricate the VMJ from a plurality of cells 400, initially identical PNN+(or NPP+) junctions can be formed to a depth of approximately 3 to 10 μm into flat wafers of high resistivity (e.g., more than 100 ohm-cm) of N type (or P type) silicon—having a thickness of approximately 0.008 inch. Subsequently, such PNN+ wafers are stacked together with a thin layer of aluminum interposed therebetween, wherein each wafer's PNN+ junction and crystal orientation can be oriented in the same direction. Moreover, aluminum-silicon eutectic alloys can be employed, or metals such as molybdenum, or tungsten, which have thermal coefficient(s) that substantially matches the thermal coefficient of silicon. Next, the silicon wafers and aluminum interfaces can be alloyed together, such that the stacked assembly can be bonded together. Buffer zones with substantially low resistivity can also be supplied in form of an inactive layer(s) arrangement that is additionally stacked upon and/or below end layers of the VMJ cell—hence implementing a barrier that protects the active layers against adverse forms of stress and/or strain (e.g., thermal/mechanical compression, torsion, moment, shear and the like—which can be induced in the VMJ during fabrication and/or operation thereof.) The surface of such cell can then be grooved to mitigate bulk recombination losses, as described in detail supra. It is to be appreciated that other material, such as germanium and titanium can also be employed. Likewise, aluminum-silicon eutectic alloys can also be employed.

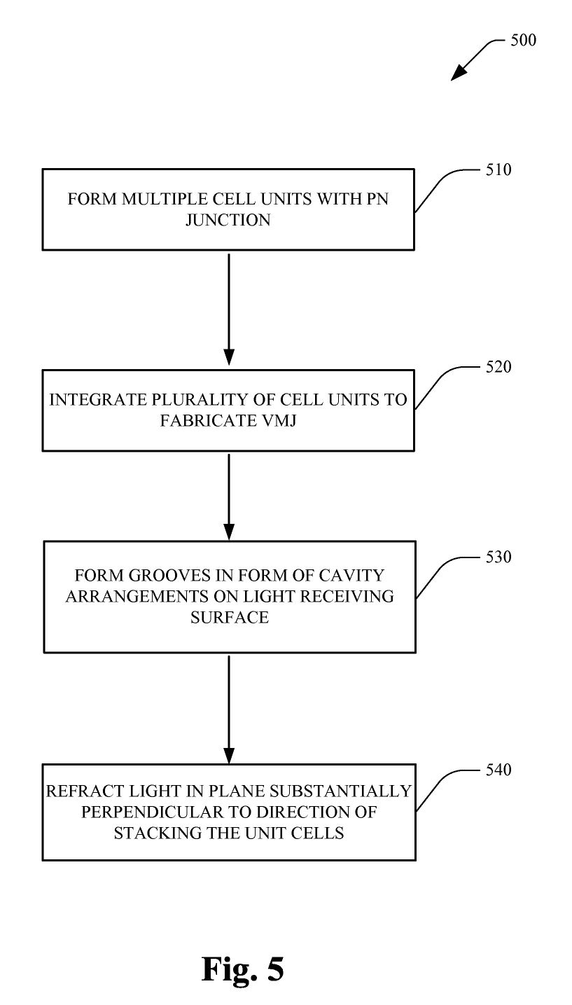

FIG. 5 illustrates a related methodology 500 of grooving a surface of a VMJ that receives light. While the exemplary method is illustrated and described herein as a series of blocks representative of various events and/or acts, the subject innovation is not limited by the illustrated ordering of such blocks. For instance, some acts or events may occur in different orders and/or concurrently with other acts or events, apart from the ordering illustrated herein, in accordance with the innovation. In addition, not all illustrated blocks, events or acts, may be required to implement a methodology in accordance with the subject innovation. Moreover, it will be appreciated that the exemplary method and other methods according to the innovation may be implemented in association with the method illustrated and described herein, as well as in association with other systems and apparatus not illustrated or described.

Initially, and at 510 multiple cell units with PN junctions are formed as described in detail supra. As explained earlier each cell unit itself can include a plurality of parallel semiconductor substrates that are stacked together. Each layer can consist of impurity doped semiconductor material that form a PN junction, and further include a “built-in” electrostatic drift field that enhance minority carrier movement toward such PN junction. Subsequently, and at 520 of plurality of such cell units are integrated to shape a VMJ, wherein buffer zones can also be implemented as a protection for such cells (e.g., stress/strain induced thereon during fabrication.) Next and at 530, on a surface of the VMJ cell that receives light cavity shaped grooves can be formed (e.g., via a dicing saw)—wherein the plane that includes the cross section configuration is substantially perpendicular to the direction of stacking the unit cells that form the VMJ. Subsequently, and at 540 incident light can be refracted in the plane that includes the cross section configuration (and/or parallel to the PN junctions), and which is substantially perpendicular to the direction of stacking the unit cells

What has been described above includes various exemplary aspects. It is, of course, not possible to describe every conceivable combination of components or methodologies for purposes of describing these aspects, but one of ordinary skill in the art may recognize that many further combinations and permutations are possible. Accordingly, the aspects described herein are intended to embrace all such alterations, modifications and variations that fall within the spirit and scope of the appended claims.

Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. A photovoltaic cell comprising:
a vertical multi junction (VMJ) photovoltaic cell that includes a plurality of integrally bonded cell units stacked along a stacking direction; and
a textured surface of the VMJ for light receipt, the textured surface for mitigation of bulk recombination losses for the VMJ.

2. The VMJ photovoltaic cell of claim 1, the stacking direction substantially perpendicular to a plane that cross sections the textured surface to create substantially repetitive cross sectional patterns.

3. The VMJ photovoltaic cell of claim 2, the substantially repetitive cross sectional pattern is that of a cavity shaped formation.

4. The VMJ photovoltaic cell of claim 3, the cavity shaped formation is at least one of a V section, or U section, or combination thereof.

5. The VMJ photovoltaic cell of claim 3, each cell of the cell units includes a plurality of parallel semiconductor substrates that are stacked together.

6. The VMJ photovoltaic cell of claim 5, a substrate includes impurity doped semiconductor material that from a PN junction.

7. The VMJ photovoltaic cell of claim 6, a substrate further includes a “built-in” electrostatic drift field that facilitates minority carrier movement towards the PN junction.

8. The VMJ photovoltaic cell of claim 7, the substrate having a back surface with reflection coatings.

9. The VMJ photovoltaic cell of claim 4, the V section positioned perpendicular to a p+nn+ unit cell, for increase of optical absorption paths.

10. The VMJ photovoltaic cell of claim 9 further comprising buffer zones with substantial low resistivity supplied in form of an inactive layer, to protect active layers.

11. A method of VMJ fabrication comprising:
integrally bonding a plurality of active layers to form a VMJ cell; and
mitigating bulk losses in the VMJ cell via a textured surface of the VMJ that receives incident light.

12. The method of claim 11 further comprising refracting the incident light in a plane that includes substantially repetitive cross sectional configuration of the textured surface.

13. The method of claim 11 further comprising directing light away from P or N doped regions of the VMJ cell.

14. The method of claim 11 further comprising refracting the incident light in a plane parallel to PN junctions of the VMJ cell.

15. The method of claim 11, the integrally bonding act further comprising stacking cell units.

16. The method of claim 15 further comprising alloying silicon wafers and aluminum interfaces to form the VMJ cell.

17. The method of claim 15 further comprising employing impurity doped semiconductor material to form PN junctions in the VMJ cell.

18. The method of claim 15 further comprising forming a cavity as part of the textured surface.

19. The method of claim 15 further comprising forming buffer zone with substantially low resistivity as part of end layers of the VMJ cell.

20. A photovoltaic cell comprising:
means for enhancing spectral response to wavelengths in a photovoltaic cell; and
means for mitigating bulk combination losses for the photovoltaic cell.
